(19) United States
(12) Patent Application Publication
(10) Pub. No.: US 2023/0305797 A1
(43) Pub. Date: Sep. 28, 2023

(54) Audio Output Modification

(71) Applicant: Meta Platforms Technologies, LLC, Menlo Park, CA (US)

(72) Inventors: Christopher James Mitchell, Ely (GB); Neil Cooper, Ely (GB); Iain Dendle, Southampton (GB); Karol Artur Jaworski, Peterborough (GB); Angus Edward Stewart, Cambridge (GB)

(21) Appl. No.: 17/656,380

(22) Filed: Mar. 24, 2022

(51) Int. Cl. G06F 3/16; H04R 1/08; H04R 1/10

(52) U.S. Cl. CPC G06F 3/165; H04R 1/08; H04R 1/1041; H04R 2430/01

(57) ABSTRACT

A device for modifying audio output based on a detected sound, the device comprising a processor configured to: determine the occurrence of a target sound in a monitored environment during the output of playback audio to a user via an audio output device; determine whether the target sound is included in a user-defined list of permitted sounds, or in a user-defined list of non-permitted sounds; and if the target sound is included in the list of permitted sounds, control the audio output device to perform at least one of: permit the target sound to be heard by the user during output of the playback audio, and notify the user that the target sound has been recognized; or if the target sound is included in the list of non-permitted sounds, control the audio output device to prevent the target sound being heard by the user during output of the playback audio.

Some example background information on sound recognition systems and methods can be found in the applicant's PCT application WO2010/070314 and US application US 2021/0104230, both of which are hereby incorporated by reference in their entirety.

### FIELD

The present disclosure generally relates to modifying audio output based on a detected sound, and to relevant devices, methods, and computer program code.

### Background

### Summary

Example embodiments relate to new applications of sound recognition systems.

The inventors have identified that existing methods of masking sounds while listening to playback audio may result in sounds being masked that are of interest to the user.

Embodiments of the present disclosure provide intelligent modification of playback audio based on recognized sounds in the surrounding environment.

According to one aspect of the present disclosure there is provided a computing device for modifying audio output based on a detected sound, the computing device comprising a processor configured to: determine the occurrence of a target sound in a monitored environment during the output of playback audio to a user via an audio output device; determine whether the target sound is included in a user-defined list of permitted sounds, or in a user-defined list of non-permitted sounds; and if the target sound is included in the user-defined list of permitted sounds, control the audio output device to perform at least one of: permit the target sound to be heard by the user during output of the playback audio, and notify the user that the target sound has been recognized; or if the target sound is included in the user-defined list of non-permitted sounds, control the audio output device to prevent the target sound being heard by the user during output of the playback audio.

The processor may be configured to determine the occurrence of the target sound in the monitored environment based on: receiving, via a microphone, audio data of audio in the monitored environment; and comparing the audio data to one or more sound models stored in a memory of the computing device, wherein the sound models correspond to one more target sounds, to recognise the target sound of said one or more target sounds in the monitored environment.

The computing device may comprise the microphone.

The computing device may be configured to determine the occurrence of the target sound in the monitored environment by receiving, via a network, a notification from a remote sound recognition device that the target sound has been recognised in the monitored environment.

The computing device may comprise the audio output device.

The audio output device may be external to the computing device, and the computing device may comprise a communications interface for communication with the audio output device.

The audio output device may comprise wearable headphones, ear buds, or bone-conduction earphones.

The processor may be configured to select the user-defined list of permitted sounds from a plurality of user-defined lists of permitted sounds based on user-defined criteria, and select the user-defined list of non-permitted sounds from a plurality of user-defined lists of non-permitted sounds based on the user-defined criteria.

The user-defined criteria may comprise one or any combination of: a user profile selected by the user, a time of day, a day of the week, a location of the computing device, an online status of the user, or an ambient noise level.

The list of permitted sounds may include at least one of a pet vocalising, a child crying, a phone ringing, laughter, clapping, a knock on a door, a doorbell ringing, glass breaking, or a sound from a vehicle.

The list of non-permitted sounds may include at least one of traffic noise, wind noise, a machine operating, a door closing, or a conversation.

The processor may be configured to permit the target sound to be heard by controlling the audio output device to alter a volume of the playback audio being played to the user.

The processor may be configured to permit the target sound to be heard by allowing playback by the audio output device to continue without alteration to the playback audio.

The processor may be configured to permit the target sound to be heard by filtering a frequency spectrum of the playback audio.

The processor may be configured to prevent the target sound being heard by the user by applying active noise cancellation to the target sound.

The processor may be configured to prevent the target sound being heard by the user by controlling the audio output device to alter a volume of the playback audio being played to the user.

The processor may be configured to prevent the target sound being heard by the user by filtering a frequency spectrum of the playback audio.

According to another aspect of the present disclosure there is provided a method for modifying audio output based on a detected sound, the method implemented on a processor contained in a computing device and comprising: determining the occurrence of a target sound in a monitored environment during the output of playback audio to a user via an audio output device; determining whether the target sound is included in a user-defined list of permitted sounds, or in a user-defined list of non-permitted sounds; and if the target sound is included in the user-defined list of permitted sounds, controlling the audio output device to perform at least one of: permit the target sound to be heard by the user during output of the playback audio, and notify the user that the target sound has been recognized; or if the target sound is included in the user-defined list of non-permitted sounds, controlling the audio output device to prevent the target sound being heard by the user during output of the playback audio.

According to another aspect of the present disclosure there is provided a non-transitory computer-readable storage medium comprising instructions which, when executed by a processor of a computing device, cause the computing device to perform any of the methods described herein.

It will be appreciated that the functionality of the devices we describe may be divided across several modules. Alternatively, the functionality may be provided in a single module or a processor. The or each processor may be implemented in any known suitable hardware such as a microprocessor, a Digital Signal Processing (DSP) chip, an Application Specific Integrated Circuit (ASIC), Field Programmable Gate Arrays (FPGAs), etc. The, or each processor may include one or more processing cores with each core configured to perform independently. The, or each processor may have connectivity to a bus to execute instructions and process information stored in, for example, a memory.

The invention further provides processor control code to implement the above-described systems and methods, for example on a general purpose computer system or on a digital signal processor (DSP). The invention also provides a carrier carrying processor control code to, when running, implement any of the above methods, in particular on a non-transitory data carrier—such as a disk, microprocessor, CD- or DVD-ROM, programmed memory such as read-only memory (Firmware), or on a data carrier such as an optical or electrical signal carrier. The code may be provided on a carrier such as a disk, a microprocessor, CD- or DVD-ROM, programmed memory such as non-volatile memory (e.g. Flash) or read-only memory (Firmware). Code (and/or data) to implement embodiments of the invention may comprise source, object or executable code in a conventional programming language (interpreted or compiled) such as C, or assembly code, code for setting up or controlling an ASIC (Application Specific Integrated Circuit) or FPGA (Field Programmable Gate Array), or code for a hardware description language such as Verilog™ or VHDL (Very high speed integrated circuit Hardware Description Language). As the skilled person will appreciate such code and/or data may be distributed between a plurality of coupled components in communication with one another. The invention may comprise a controller which includes a microprocessor, working memory and program memory coupled to one or more of the components of the system.

These and other aspects will be apparent from the embodiments described in the following. The scope of the present disclosure is not intended to be limited by this summary nor to implementations that necessarily solve any or all of the disadvantages noted.

### BRIEF DESCRIPTION OF THE DRAWINGS

For a better understanding of the present disclosure and to show how embodiments may be put into effect, reference is made to the accompanying drawings in which:

FIG. 1 shows a block diagram of an example computing device;

FIG. 2 is a flow chart illustrating a process for modifying audio output based on a detected sound;

FIG. 3 shows a block diagram of a computing device and a remote audio output device;

FIG. 4 shows a block diagram of a computing device and a remote microphone; and

FIG. 5 shows a block diagram of a computing device and a remote sound recognition device.

### DETAILED DESCRIPTION

Embodiments will now be described by way of example only.

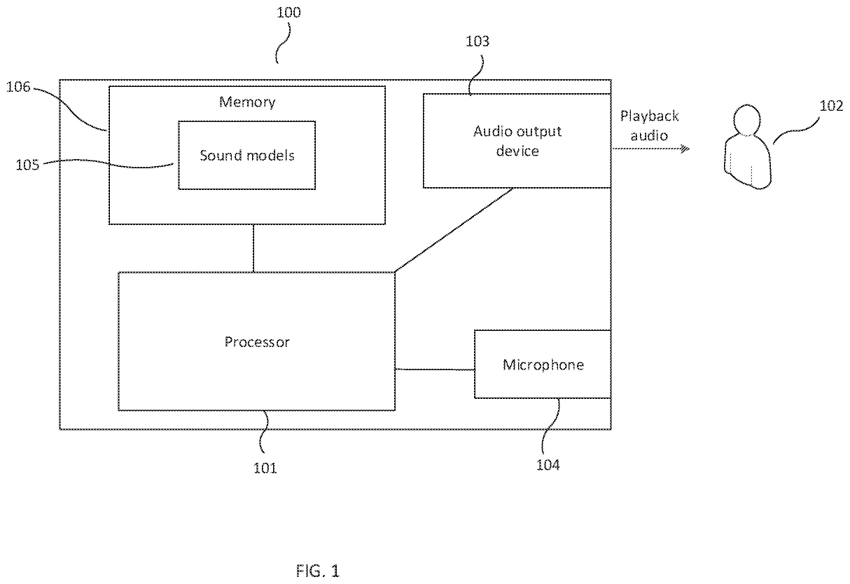

FIG. 1 shows a computing device 100 in a monitored environment which may be an indoor space (e.g. a house, a gym, a shop, a railway station etc.), an outdoor space or in a vehicle. The computing device 100 is associated with a user 102.

It will be appreciated from the below that FIG. 1 is merely illustrative and the computing device 100 of embodiments of the present disclosure may not comprise all of the components shown in FIG. 1.

The computing device 100 may be a PC, a mobile computing device such as a laptop, smartphone, tablet-PC, a virtual reality (VR) headset, a consumer electronics device (e.g. a TV), or other electronics device (e.g. an in-vehicle device). The computing device 100 may be a mobile device such that the user 102 can move the computing device 100 around the monitored environment. Alternatively, the computing device 100 may be fixed at a location in the monitored environment (e.g. a panel mounted to a wall of a home). Alternatively, the device may be worn by the user 102 by attachment to or sitting on a body part or by attachment to a piece of garment.

The computing device 100 comprises a processor 101 coupled to memory 106.

The functionality of the processor 101 described herein may be implemented in code (software) stored on a memory (e.g. memory 106) comprising one or more storage media, and arranged for execution on a processor comprising one or more processing units. The storage media may be integrated into and/or separate from the processor 101.

The code is configured so as when fetched from the memory and executed on the processor to perform operations in line with embodiments discussed herein. Alternatively, it is not excluded that some or all of the functionality of the processor 101 is implemented in dedicated hardware circuitry (e.g. ASIC(s), simple circuits, gates, logic, and/or configurable hardware circuitry like an FPGA).

The computing device 100 comprises a microphone 104. The microphone 104 is configured to sense audio in a monitored environment of the computing device 100 and supply audio data to the processor 101. The microphone 104 may be external to the computing device 100 and be coupled to the computing device 100 by way of a wired or wireless connection.

The computing device 100 further comprises an audio output device 103. In some embodiments the audio output device 103 may be a speaker. The audio output device 103 is configured to output playback audio such that the playback audio is audible to the user 102. The audio output device 103 may be external to the computing device 100 and be coupled to the computing device 100 by way of a wired or wireless connection.

The processor 101 is configured to recognise a target sound using the audio data received from the microphone 104. In some embodiments, the processor 101 is configured to recognise a target sound by comparing the audio data to one or more sound models 105 stored in the memory 106. The sound model(s) 105 may be associated with one or more target sounds (which may be for example, a pet vocalising, a child crying, a phone ringing, laughter, clapping, a door closing, a machine operating, and a conversation).

As shown in FIG. 1, the computing device 100 may store the sound model(s) 105 locally (in memory 106) and so does not need to be in constant communication with any remote system in order to identify a captured sound. Alternatively, the storage of the sound model(s) 105 is on a remote server (not shown in FIG. 1) coupled to the computing device 100, and sound recognition software on the remote server is used to perform the processing of audio received from the computing device 100 to recognise that a sound captured by the computing device 100 corresponds to a target sound. In these embodiments, the computing device 100 transmits the audio data to the remote server for processing, and receives an indication of the target sound. This advantageously reduces the processing performed on the computing device 100.

Further information on the sound model(s) 105 is provided below.

A sound model associated with a target sound is generated based on processing a captured sound corresponding to the target sound class. Preferably, multiple instances of the same sound are captured more than once in order to improve the reliability of the sound model generated of the captured sound class.

The target sound may be verbal or non-verbal. Within this application the term verbal is used to refer to any sound produced by human vocal cords, while non-verbal is used to refer to any sound not produced by human vocal cords. If the target sound is a verbal sound, it may be human speech or may be a non-speech verbal sound such as laughter or crying.

In order to generate a sound model the captured sound class(es) are processed and parameters are generated for the specific captured sound class. The generated sound model comprises these generated parameters and other data which can be used to characterise the captured sound class.

There are a number of ways a sound model associated with a target sound class can be generated. The sound model for a captured sound may be generated using machine learning techniques or predictive modelling techniques such as: hidden Markov model, neural networks, support vector machine (SVM), decision tree learning, etc.

The applicant's PCT application WO2010/070314, which is incorporated by reference in its entirety, describes in detail various methods to identify sounds. Further methods are also described in the applicant's US application US 2021/0104230, which is also incorporated by reference in its entirety. The skilled person would appreciate that various methods of sound identification based on machine learning exist and can be implemented for performing the sound detection described herein. In the following we describe one particular method merely by way of example.

Broadly speaking an input sample sound is processed by decomposition into frequency bands, and optionally de-correlated, for example, using PCA/ICA, and then this data is compared to one or more Markov models to generate log likelihood ratio (LLR) data for the input sound to be identified. A (hard) confidence threshold may then be employed to determine whether or not a sound has been identified; if a “fit” is detected to two or more stored Markov models then preferably the system picks the most probable. A sound is “fitted” to a model by effectively comparing the sound to be identified with expected frequency domain data predicted by the Markov model. False positives are reduced by correcting/updating means and variances in the model based on interference (which includes background) noise.

It will be appreciated that other techniques than those described herein may be employed to create a sound model.

The sound recognition system may work with compressed audio or uncompressed audio. For example, the time-frequency matrix for a 44.1 KHz signal might be a 1024 point FFT with a 512 overlap. This is approximately a 20 milliseconds window with 10 millisecond overlap. The resulting 512 frequency bins are then grouped into sub bands, or example quarter-octave ranging between 62.5 to 8000 Hz giving 30 sub-bands.

A lookup table can be used to map from the compressed or uncompressed frequency bands to the new sub-band representation bands. For the sample rate and STFT size example given the array might comprise of a (Bin size÷2)×6 array for each sampling-rate/bin number pair supported. The rows correspond to the bin number (centre)—STFT size or number of frequency coefficients. The first two columns determine the lower and upper quarter octave bin index numbers. The following four columns determine the proportion of the bins magnitude that should be placed in the corresponding quarter octave bin starting from the lower quarter octave defined in the first column to the upper quarter octave bin defined in the second column. e.g. if the bin overlaps two quarter octave ranges the 3 and 4 columns will have proportional values that sum to 1 and the 5 and 6 columns will have zeros. If a bin overlaps more than one sub-band more columns will have proportional magnitude values. This example models the critical bands in the human auditory system. This reduced time/frequency representation is then processed by the normalisation method outlined. This process is repeated for all frames incrementally moving the frame position by a hop size of 10 ms. The overlapping window (hop size not equal to window size) improves the time-resolution of the system. This is taken as an adequate representation of the frequencies of the signal which can be used to summarise the perceptual characteristics of the sound. The normalisation stage then takes each frame in the sub-band decomposition and divides by the square root of the average power in each sub-band. The average is calculated as the total power in all frequency bands divided by the number of frequency bands. This normalised time frequency matrix is the passed to the next section of the system where a sound recognition model and its parameters can be generated to fully characterise the sound's frequency distribution and temporal trends.

The next stage of the sound characterisation requires further definitions.

A machine learning model is used to define and obtain the trainable parameters needed to recognise sounds. Such a model is defined by:
a set of trainable parameters 8, for example, but not limited to, means, variances and transitions for a hidden Markov model (HMM), support vectors for a support vector machine (SVM), weights, biases and activation functions for a deep neural network (DNN),
a data set with audio observations o and associated sound labels I, for example a set of audio recordings which capture a set of target sounds of interest for recognition such as, e.g., baby cries, dog barks or smoke alarms, as well as other background sounds which are not the target sounds to be recognised and which may be adversely recognised as the target sounds. This data set of audio observations is associated with a set of labels I which indicate the locations of the target sounds of interest, for example the times and durations where the baby cry sounds are happening amongst the audio observations o.

Generating the model parameters is a matter of defining and minimising a loss function L(θ|o,|) across the set of audio observations, where the minimisation is performed by means of a training method, for example, but not limited to, the Baum-Welsh algorithm for HMMs, soft margin minimisation for SVMs or stochastic gradient descent for DNNs.

To classify new sounds, an inference algorithm uses the model to determine a probability or a score P(C|o,θ) that new incoming audio observations o are affiliated with one or several sound classes C according to the model and its parameters θ. Then the probabilities or scores are transformed into discrete sound class symbols by a decision method such as, for example but not limited to, thresholding or dynamic programming.

The models will operate in many different acoustic conditions and as it is practically restrictive to present examples that are representative of all the acoustic conditions the system will come in contact with, internal adjustment of the models will be performed to enable the system to operate in all these different acoustic conditions. Many different methods can be used for this update. For example, the method may comprise taking an average value for the sub-bands, e.g. the quarter octave frequency values for the last T number of seconds. These averages are added to the model values to update the internal model of the sound in that acoustic environment.

In embodiments whereby the computing device 100 performs audio processing to recognise a target sound in the monitored environment, this audio processing comprises the microphone 104 of the computing device 100 capturing a sound, and the processor 101 analysing this captured sound. In particular, the processor 101 compares the captured sound to the one or more sound models 105 stored in memory 106. If the captured sound matches with the stored sound model(s) 105, then the sound is identified as the target sound.

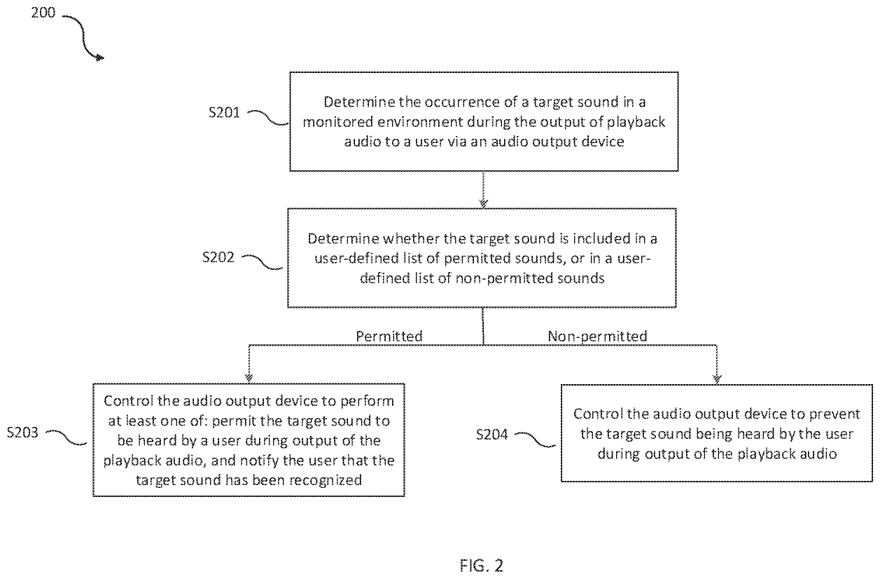

FIG. 2 is a flowchart illustrating an exemplary method 200 to modify audio output in an embodiment. The steps of the process 200 are performed by the processor 101.

The method 200 is executed while the audio output device 103 is outputting playback audio to a user 102. The playback audio may be, but is not limited to, music, a radio station, a podcast, or audio accompanying a video, video game, or application.

At step S201, the processor 101 determines the occurrence of a target sound in a monitored environment, which is typically the ambient environment of the user 102 and computing device 100.

The microphone 104 is arranged to capture audio from the monitored environment. This audio may be converted by the processor 101 into digital audio data, such as digital audio samples. The processor 101 may optionally compress the digital audio data prior to further analysis. The processor 101 may execute sound recognition software that compares the digital audio data to the one or more sound models 105 stored in memory 106. If the audio data matches with a sound model corresponding to a target sound, the processor 101 determines that the target sound occurred in the monitored environment.

Alternatively, at step S201 the processor 101 may transmit the audio data to the remote server for processing, and determine the occurrence of a target sound in the monitored environment based on receiving a message from the remote server. The remote server may store the sound model(s) 105, and be configured to compare the audio data to the one or more sound models 105 to determine the occurrence of a non-speech target sound based on the audio data matching with one of the sound models 105.

At step S202 the processor 101 determines whether the target sound is included in a user-defined list of permitted sounds, or in a user-defined list of non-permitted sounds. These lists are determined by the user 102 in advance of the method 200 being executed by the processor 101. The lists may be stored in the memory 106, or may be stored in another memory coupled to the processor 101 or in a remote memory accessed by the processor 101 via a wired or wireless connection. For example, the lists may be stored in a central database accessed by several different computing devices 100.

The user-defined list of permitted sounds includes sounds that the user 102 deems to be of interest, such that the user 102 wishes the playback audio to be interrupted if one of the permitted sounds occurs so that the user 102 can hear the permitted sound.

For example, if the user 102 is taking part in a video call but expecting a delivery, they may include the sounds of a doorbell ringing or a knock on a door in the list of permitted sounds.

As another example, if the user 102 is watching a film using headphones while their baby is asleep, they may wish the film audio to be interrupted if their baby awakes and begins to cry. In this case they may include the sound of a baby crying on the list of permitted sounds.

The user-defined list of non-permitted sounds includes sounds that the user 102 deems not to be of interest, such that the user 102 does not wish to hear the non-permitted sounds while listening to the playback audio.

For example, if the user 102 is listening to music in the passenger seat of a car, they may not wish to hear the wind noise arising from the car's motion, or the sounds of other traffic. In this case they may include wind noise and traffic noise in the list of non-permitted sounds.

As another example, if the user 102 is working in a café while listening to music on headphones, they may not wish to hear the sounds of conversations between other people in the café, or the sounds of the coffee machine operating. In this case they may include conversations and machine sounds on the list of non-permitted sounds.

The user-defined lists of permitted and non-permitted sounds may be configured to change automatically depending on user-defined criteria configured in advance by the user 102 while configuring the user-defined lists.

The criteria may include, but are not limited to, a user profile selected by the user 102, a time of day, a day of the week, a location of the computing device 100, an online status of the user, or an ambient noise level. The criteria may also be a combination of these examples. In this application “online status” means a status on a communication or social media platform indicating whether or not the user 102 is online and/or active.

For example, the processor 101 may be configured with a “Home” profile and a “Work” profile such that the user 102 can manually switch between these profiles. The “Home” profile may, for instance, include the sounds of the user's children of the list of permitted sounds, while the “Work” profile includes the sounds of the user's children on the list of non-permitted sounds. This ensures that the children do not interrupt the user's work while allowing them to be heard at other times.

In another example, a similar effect may be achieved by configuring the criteria such that the sounds of the user's children are automatically added to the list of non-permitted sounds on weekdays during working hours, and added to the list of permitted sounds at weekends and on weekdays outside working hours.

In a further example, the lists of permitted and non-permitted sounds may change as the user 102 moves between different geographic locations. For example, the user 102 may configure different lists to apply automatically when they are at home, at the office, at a café, or on a road (implying that they are in a vehicle).

It is anticipated that the list of permitted sounds and the list of non-permitted sounds are mutually exclusive. That is, if a sound is on the list of permitted sounds it cannot be on the list of non-permitted sounds, and vice-versa.

If the target sound is determined to be included in the user-defined list of permitted sounds, the processor 101 executes step S203. At step S203, the processor 101 may control the audio output device 103 to permit the target sound to be heard by the user 102 during output of the playback audio.

In order to permit the target sound to be heard by the user 102, the processor 101 may for example control the audio output device 103 to decrease the volume of the playback audio. Instead or in addition, the processor 101 may control the audio output device 103 to adjust the volume differently for different frequency components of the playback audio. For example, if the target sound is high-pitched, such as a pet cat's meow, the processor 101 may control the audio output device 103 to reduce the volume of high-frequency components of the playback audio to permit the target sound to be heard by the user.

Alternatively, it may not be necessary for the playback audio to be altered for the user 102 to hear the target sound. For example, the target sound may be louder than the playback audio. In this case the processor 101 may permit the playback audio to continue without alteration.

Alternatively, the processor 101 may permit the target sound to be heard by the user by controlling the audio output device 103 to output audio associated with the target sound. The audio associated with the target sound may correspond to particular frequencies within the target sound, or may correspond to particular sections of the target sound in time. The audio associated with the target sound may act to enhance or reduce the corresponding frequencies or sections of the target sound.

At step S203 the processor 101 may additionally or alternatively be configured to control the audio output device 103 to notify the user 102 that the target sound has been detected. For example, a notification sound may be played over the playback audio. In another example, a spoken message may be played via text-to-speech software informing the user 102 of the target sound that has been detected.

If the target sound is determined to be included in the user-defined list of non-permitted sounds, the processor 101 executes step S204. In this step, the processor 101 controls the audio output device 103 to prevent the target sound being heard by the user 102 during output of the playback audio.

In order to prevent the target sound being heard by the user 102, the processor 101 may for example control the audio output device 103 to increase the volume of the playback audio. Instead or in addition, the processor 101 may control the audio output device 103 to adjust the volume differently for different frequency components of the playback audio. For example, if the target sound is low-pitched, such as the drone of a machine, the processor 101 may control the audio output device 103 to increase the volume of low-frequency components of the playback audio to prevent the target sound being heard by the user.

Alternatively, the processor 101 may prevent the target sound being heard by the user 102 by controlling the audio output device 103 to apply active noise cancellation (ANC) techniques to cancel the target sound.

Alternatively, the processor 101 may prevent the target sound being heard by the user by controlling the audio output device 103 to output audio associated with the target sound. The audio associated with the target sound may correspond to particular frequencies within the target sound, or may correspond to particular sections of the target sound in time. The audio associated with the target sound may act to enhance or reduce the corresponding frequencies or sections of the target sound.

It will be appreciated that a target sound may be recognised that is included in neither the list of permitted sounds nor the list of non-permitted sounds. In this case the processor 101 executes neither of the steps S203 or S204.

It will be appreciated that, while the processor 101 is taking action in response to detecting a first target sound, a further target sound may be detected. In this case the processor 101 may repeat the method 200 in order to account for the further target sound in addition to the first target sound.

For example, if the sound of a dog barking is recognized, the processor 101 may initially act by applying a filter to the playback audio in order to prevent the user from hearing the barking. If a second dog then also begins barking, the processor 101 may adjust the filter accordingly.

It is also possible for the processor 101 to initially anticipate a target sound based on information other than sound recognition. For example, the processor 101 may detect that the computing device 100 has been placed in a nursery. In this instance the processor 101 may anticipate a baby beginning to cry, and may control the audio output device 103 to output audio associated with the target sound of a baby crying in anticipation of detecting this target sound.

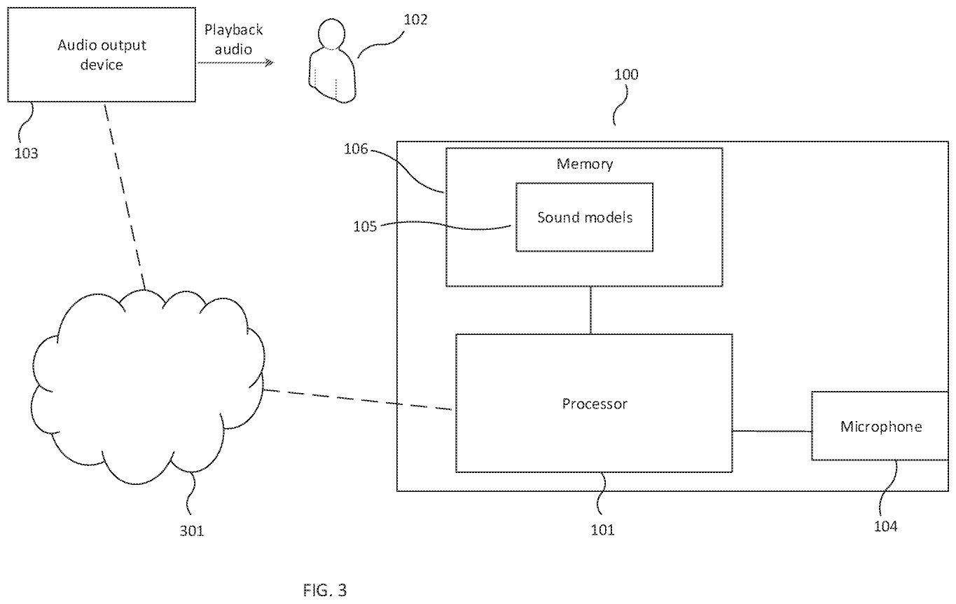

FIGS. 3-5 show alternative configurations of the computing device 100.

FIG. 3 shows an embodiment wherein the audio output device 103 is external to the computing device 100 and wirelessly coupled to the computing device 100 via a network 301.

In this embodiment the audio output device 103 may be a set of wearable headphones, ear buds, or bone-conduction earphones.

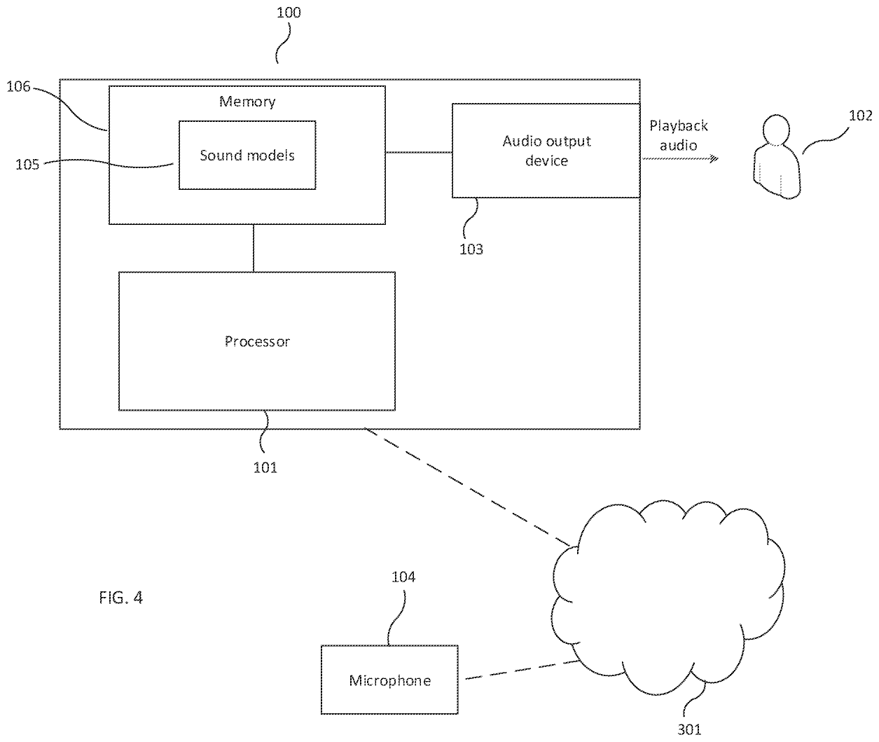

FIG. 4 shows an embodiment wherein the microphone 104 is external to the computing device 100 and wirelessly coupled to the computing device 100 via a network 301.

In this embodiment the monitored environment is the vicinity of the microphone 104 which may be in a different location from the user 102 and the computing device 100.

It will be appreciated that the embodiments of FIGS. 3 and 4 are not mutually exclusive.

That is, it may be that both the microphone 104 and the audio output device 103 are remote and wirelessly coupled to the computing device 100 via a network 301. In this embodiment the microphone 104 and the audio output device 103 may be separate remote devices, or may be combined into a single remote device.

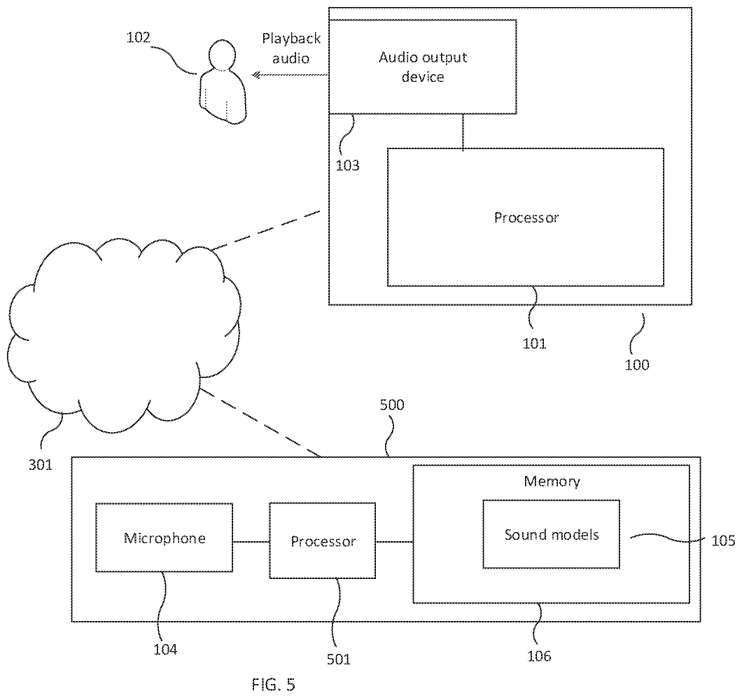

FIG. 5 shows an embodiment wherein the computing device 100 is wirelessly coupled via a network 301 to a sound recognition device 500. In this embodiment the microphone 104 and the memory 106 storing the one or more sound models 105 are located in the sound recognition device 500, not in the computing device 100. The sound recognition device 500 further comprises a processor 501 separate from the processor 101 of the computing device 100.

In this embodiment, the processor 101 of the computing device 100 executes S201 by receiving a notification from the sound recognition device 500 that a target sound has been recognized in the monitored environment.

The microphone 104 is arranged to capture audio from the monitored environment. This audio may be converted by the processor 501 of the sound recognition device 500 into digital audio data, such as digital audio samples. The processor 501 may optionally compress the digital audio data prior to further analysis. The processor 501 then executes sound recognition software that compares the digital audio data to the one or more sound models 105 stored in memory 106. If the audio data matches with a sound model corresponding to a target sound, the processor 501 of the sound recognition device 500 causes a notification to be sent to the processor 101 of the computing device 100 via the network 301. Upon receiving this notification, the processor 101 of the computing device 100 completes step S201 by determining that the target sound has occurred in the monitored environment.

Step S202 and any subsequent steps are then performed by the processor 101 of the computing device 100 as described above in reference to FIG. 2.

For example, the sound recognition device 500 may be a smart doorbell configured to detect and recognise the sound of someone knocking on the user's front door. The smart doorbell may, for example, send a notification to a computing device 100 that is the user's television. A processor 101 within the television may determine that the sound of a knock on a door is on the user-defined list of permitted sounds defined above, and may accordingly lower the volume of the television audio via the audio output device 103 which is the television speakers. In this case the monitored environment is the vicinity of the front door, where the smart doorbell comprising the microphone 104 is located.

It will be appreciated that the embodiment of FIG. 5 can be combined with either or both of the embodiments of FIGS. 3 and 4. That is, the computing device 100 may communicate with a separate audio output device 103, and/or the sound recognition device 500 may communicate with a remote microphone 104. Each of these connections may be wired or wireless.

Thus, it can be seen that embodiments described herein use sound recognition to improve a user's listening experience by intelligently masking ambient sounds based on user preferences.

1. A computing device for modifying audio output based on a detected sound, the computing device comprising a processor configured to:
determine the occurrence of a target sound in a monitored environment during the output of playback audio to a user via an audio output device;
determine whether the target sound is included in a user-defined list of permitted sounds, or in a user-defined list of non-permitted sounds; and
if the target sound is included in the user-defined list of permitted sounds, control the audio output device to perform at least one of: permit the target sound to be heard by the user during output of the playback audio, and notify the user that the target sound has been recognized; or
if the target sound is included in the user-defined list of non-permitted sounds, control the audio output device to prevent the target sound being heard by the user during output of the playback audio.

2. The computing device of claim 1, wherein the processor is configured to determine the occurrence of the target sound in the monitored environment based on:
receiving, via a microphone, audio data of audio in the monitored environment; and
comparing the audio data to one or more sound models stored in a memory of the computing device, wherein the sound models correspond to one more target sounds, to recognise the target sound of said one or more target sounds in the monitored environment,
optionally wherein the computing device comprises the microphone.

3. The computing device of claim 1, wherein the processor is configured to determine the occurrence of the target sound in the monitored environment by receiving, via a network, a notification from a remote sound recognition device that the target sound has been recognised in the monitored environment.

4. The computing device of claim 1, wherein the computing device comprises the audio output device.

5. The computing device of claim 1, wherein the audio output device is external to the computing device, and the computing device comprises a communications interface for communication with the audio output device.

6. The computing device of claim 5, wherein the audio output device comprises wearable headphones, ear buds, or bone-conduction earphones.

7. The computing device of claim 1, wherein the processor is configured to select the user-defined list of permitted sounds from a plurality of user-defined lists of permitted sounds based on user defined criteria, and select the user-defined list of non-permitted sounds from a plurality of user-defined lists of non-permitted sounds based on the user-defined criteria.

8. The computing device of claim 7, wherein the user defined criteria comprise one or any combination of: a user profile selected by the user, a time of day, a day of the week, a location of the computing device, an online status of the user, or an ambient noise level.

9. The computing device of claim 1, wherein the list of permitted sounds includes at least one of a pet vocalising, a child crying, a phone ringing, laughter, clapping, a knock on a door, a doorbell ringing, glass breaking, a sound from a vehicle, or a transient impulsive sound.

10. The computing device of claim 1, wherein the list of non-permitted sounds includes at least one of traffic noise, wind noise, a machine operating, a door closing, or a conversation, or a broad-spectrum sound.

11. The computing device of claim 1, wherein the processor is configured to permit the target sound to be heard by the user by controlling the audio output device to alter a volume of the playback audio being played to the user.

12. The computing device of claim 1, wherein the processor is configured to permit the target sound to be heard by the user by allowing playback by the audio output device to continue without alteration to the playback audio.

13. The computing device of claim 1, wherein the processor is configured to permit the target sound to be heard by the user by filtering a frequency spectrum of the playback audio.

14. The computing device of claim 1, wherein the processor is configured to permit the target sound to be heard by the user by controlling the audio output device to output audio associated with the target sound, wherein the audio associated with the target sound is operable to enhance or reduce one or more temporal or frequency components of the target sound.

15. The computing device of claim 1, wherein the processor is configured to prevent the target sound being heard by the user by applying active noise cancellation to the target sound.

16. The computing device of claim 1, wherein the processor is configured to prevent the target sound from being heard by the user by controlling the audio output device to alter a volume of the playback audio being played to the user.

17. The computing device of claim 1, wherein the processor is configured to prevent the target sound from being heard by the user by filtering a frequency spectrum of the playback audio.

18. The computing device of claim 1, wherein the processor is configured to prevent the target sound being heard by the user by controlling the audio output device to output audio associated with the target sound, wherein the audio associated with the target sound is operable to enhance or reduce one or more temporal or frequency components of the target sound.

19. A method for modifying audio output based on a detected sound, the method implemented on a processor contained in a computing device and comprising:
determining the occurrence of a target sound in a monitored environment during the output of playback audio to a user via an audio output device;
determining whether the target sound is included in a user-defined list of permitted sounds, or in a user-defined list of non-permitted sounds; and
if the target sound is included in the user-defined list of permitted sounds, controlling the audio output device to perform at least one of: permit the target sound to be heard by the user during output of the playback audio, and notify the user that the target sound has been recognized; or
if the target sound is included in the user-defined list of non-permitted sounds, controlling the audio output device to prevent the target sound being heard by the user during output of the playback audio.

20. A non-transitory computer-readable storage medium comprising instructions which, when executed by a processor of a computing device, cause the computing device to perform a method comprising:
determining the occurrence of a target sound in a monitored environment during the output of playback audio to a user via an audio output device;
determining whether the target sound is included in a user-defined list of permitted sounds, or in a user-defined list of non-permitted sounds; and
if the target sound is included in the user-defined list of permitted sounds, controlling the audio output device to perform at least one of: permit the target sound to be heard by the user during output of the playback audio, and notify the user that the target sound has been recognized; or
if the target sound is included in the user-defined list of non-permitted sounds, controlling the audio output device to prevent the target sound being heard by the user during output of the playback audio.
